(19) United States
(12) Patent Application Publication
(10) Pub. No.: US 2008/0191325 A1
(43) Pub. Date: Aug. 14, 2008

(54) SEMICONDUCTOR DEVICE AND PACKAGING STRUCTURE THEREFOR

(75) Inventor: KENICHI SHIRASAKA, Hamamatsu-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION, Hamamatsu-Shi (JP)

(21) Appl. No.: 12/021,746

(22) Filed: Jan. 29, 2008

(30) Foreign Application Priority Data
Jan. 31, 2007 (JP) JP2007-020978
May 21, 2007 (JP) JP2007-133967

(51) Int. Cl. H01L 23/498

(52) U.S. Cl. 257/666; 257/E23.087; 257/E23.06

(57) ABSTRACT

A semiconductor device includes two semiconductor chips having different guarantee temperatures, which are individually mounted on two stages distanced from each other and are sealed with a resin mold. One semiconductor chip includes a heating circuit causing a heating temperature that is higher than the guarantee temperature of another semiconductor chip, and the backside of the stage thereof is exposed externally of the resin mold. This reduces the amount of heat transmitted from one semiconductor chip to another semiconductor chip, thus improving the reliability of the semiconductor device. Alternatively, two semiconductor chips having different heights are mounted on a single stage, wherein one semiconductor chip causing a high heating temperature is lowered in height in comparison with another semiconductor chip, thus increasing the heat-transmission path between the semiconductor chips and thus reducing the heat-dissipation path for dissipating heat of one semiconductor chip to a substrate.

### BACKGROUND OF THE INVENTION

1. Field of the Invention

The present invention relates to semiconductor devices and packaging structures for mounting semiconductor devices on substrates.

This application claims priority on Japanese Patent Application No. 2007-20978 and Japanese Patent Application No. 2007-133967, the contents of which are incorporated herein by reference.

2. Description of the Related Art

Conventionally, various types of semiconductor devices have been developed and manufactured by various manufacturers. For example, Japanese Patent Application Publication No. 2000-150725 discloses a structure in which a semiconductor chip is mounted on the surface of a rectangular stage and is sealed with a resin mold. In this type of semiconductor device, the backside of the stage is exposed outside of the resin mold and joins a substrate (or a circuit board) via solder for the purpose of efficiently dissipating heat generated by semiconductor chips.

Some of the conventionally-known semiconductor devices having the aforementioned structure may each include two semiconductor chips having different guarantee temperatures (or operation temperatures), which are mounted on the surface of a single stage.

However, when two semiconductor chips having different guarantee temperatures are mounted on the surface of a single substrate of a semiconductor device, heat generated by a semiconductor chip having a higher guarantee temperature is unexpectedly transmitted to another semiconductor chip having a lower guarantee temperature so that a temperature of another semiconductor chip exceeds its guarantee temperature, thus causing operational error in the semiconductor device.

When two semiconductor chips having different guarantee temperatures are mounted on a single stage, heat transmission occurs between the two semiconductor chips via the stage and resin mold, whereby the temperature of a case (or a package) increases so that the temperature of the semiconductor chip may exceed the guarantee temperature guaranteeing the normal operation, thus causing operational error in the semiconductor device. The guarantee temperature is determined with respect to each semiconductor chip based on the case temperature, junction temperature, and surrounding temperature, for example.

### SUMMARY OF THE INVENTION

It is an object of the present invention to provide a semiconductor device allowing heat generated by each semiconductor chip to efficiently dissipate, thus suppressing heat conduction between plural semiconductor chips having different heating temperatures.

The present invention is also applicable to a semiconductor device includes plural semiconductor chips having different guarantee temperatures (or operating temperatures), and a semiconductor device includes plural semiconductor chips, wherein the heating temperature of one of the semiconductor chips becomes higher than the guarantee temperature of the other of the semiconductor chips.

In a first aspect of the present invention, a semiconductor device includes a plurality of stages each having a rectangular shape, which are positioned in the same plane and which are distanced from each other, a plurality of semiconductor chips including a first semiconductor chip and a second semiconductor chip, which are individually mounted on the surfaces of the stages, wherein the first semiconductor chip includes a heating circuit causing a heating temperature that is higher than a heating temperature caused by the second semiconductor chip, and a resin mold for sealing the semiconductor chips and the stages therein, wherein the backside of the stage for mounting the first semiconductor chip is exposed externally of the resin mold.

Since the stages for individually mounting the first and second semiconductor chips having different guarantee temperatures are distanced from each other within the resin mold, it is possible to reduce the amount of heat that is generated by the heating circuit of the first semiconductor chip and that is transmitted to the second semiconductor chip. In other words, it is possible to prevent the temperature of the second semiconductor chip from exceeding the guarantee temperature. When the semiconductor device is mounted on a substrate (or a circuit board), the backside of the stage exposed externally of the resin mold is bonded to a heat-dissipation pad arranged on the substrate via solder; hence, it is possible to efficiently transmit the heat of the first semiconductor chip to the substrate.

In the above, the heating circuit is formed in a prescribed region of the first semiconductor chip that is distanced from the second semiconductor chip. This increases the distance between the heating circuit of the first semiconductor chip and the second semiconductor chip; hence, it is possible to further reduce the amount of heat transmitted from the first semiconductor chip to the second semiconductor chip.

In addition, a pair of stages are positioned adjacent to each other and are integrally interconnected together by way of at least one interconnection member whose width is smaller than the width of each stage.

In the manufacturing of the semiconductor device, the resin mold is formed in such a way that the stages for individually mounting the semiconductor chips are arranged inside of a cavity of a metal mold, into which a melted resin is introduced so as to form the resin mold.

In order to make the backside of the stage be exposed externally of the resin mold, it is necessary to arrange the stage inside of the cavity of the metal mold. Herein, the interconnection member prevents the stage from unexpectedly floating above the interior wall of the cavity due to the flowing of the melted resin; hence, it is possible to reliably make the backside of the stage be exposed externally of the resin mold. The interconnection member has a small width, which is smaller than the width of the stage, so as to reduce the amount of heat transmitted from the first semiconductor chip to the second semiconductor chip.

The interconnection member is formed by way of a recess that is recessed from the backside of the stage in its thickness direction. Herein, the interconnection member is completely embedded inside of the resin mold although the backsides of the stages interconnected via the interconnection member are exposed externally of the resin mold. When the semiconductor device is mounted on the substrate in such a way that the stages join the heat-dissipation pads of the substrate via solder, it is possible to reliably prevent the solder from leaking and spreading over the stages; in other words, it is possible to reliably prevent the heat generated by the first semiconductor chip from being transmitted to the second semiconductor chip via the solder.

Both ends of one stage and both ends of another stage can be interconnected together via the interconnection member in the width direction. This increases the heat conduction path via which the heat of the first semiconductor chip is transmitted to the second semiconductor chip via the interconnection member; hence, it is possible to further reduce the amount of heat transmitted from the first semiconductor chip to the second semiconductor chip.

A packaging structure adapted to the semiconductor device includes at least one heat-dissipation pad having a prescribed area for joining the backside of the stage for mounting the first semiconductor chip, wherein the overall area of the heat-dissipation pad is larger than the exposed area of the backside of the stage exposed externally of the resin mold, and wherein the heat-dissipation pad is covered with a resist film except for the prescribed area that is positioned opposite to the backside of the stage. This makes it possible to diffuse the heat of the first semiconductor chip to the heat-dissipation pad whose overall area is larger than the exposed area of the stage; hence, it is possible to efficiently dissipate the heat of the first semiconductor chip. Since the heat-dissipation pad is covered with the resist film, even when the backside of another stage (other than the stage for mounting the first semiconductor chip) is positioned opposite to the heat-dissipation pad, it is possible to easily prevent another stage from joining the heat-dissipation pad via solder. As described above, the packaging structure is designed to prevent the heat of the first semiconductor chip from being unexpectedly transmitted to the second semiconductor chip via the heat-dissipation pad.

In short, since the semiconductor chips are individually mounted on the stages that are distanced from each other, it is possible to reduce the amount of heat that is generated by the first semiconductor chip having a relatively high guarantee temperature and that is transmitted to the second semiconductor chip having a relatively low guarantee temperature; thus, it is possible to improve the reliability of the semiconductor device.

In a second aspect of the present invention, a semiconductor device includes a plurality of semiconductor chips, e.g., a first semiconductor chip and a second semiconductor chip, a single stage having a rectangular shape, on which surface the plurality of semiconductor chips are mounted, a plurality of leads whose first ends are electrically connected to the plurality of semiconductor chips, and a resin mold for sealing the semiconductor chips, the stage, and the first ends of the leads in such a way that a prescribed area of the backside of the stage and second ends of the leads are exposed externally thereof, wherein the first semiconductor chip causing a high heating temperature is lowered in height in comparison with the second semiconductor chip. Herein, the first semiconductor chip is mounted on a first region of the stage, and the second semiconductor chip is mounted on a second region of the stage. In addition, the guarantee temperature of the second semiconductor chip is lower than the guarantee temperature of the first semiconductor chip.

When the semiconductor device is mounted on a substrate (or a circuit board), the exposed area of the backside of the stage, which is exposed externally of the resin mold, joins a heat-dissipation pad of the substrate via solder. Since, compared with the surface of the second semiconductor chip, the surface of the first semiconductor chip is positioned close to surface of the stage, it is possible to reduce the heat-dissipation path for dissipating heat of the first semiconductor chip to the heat-dissipation pad of the substrate via the stage and solder. That is, it is possible to efficiently dissipate the heat of the first semiconductor chip to the substrate.

In addition, the semiconductor device is designed to increase the distance between the surfaces of the semiconductor chips without increasing the gap therebetween, wherein the direction lying from the surface of the first semiconductor chip to the surface of the second semiconductor chip is reverse to the direction of the heat-dissipation path lying from the surface of the first semiconductor chip to the substrate. This makes it possible to prevent the heat of the first semiconductor chip from being excessively transmitted to the second semiconductor chip; that is, it is possible to prevent the temperature of the second semiconductor chip from exceeding the guarantee temperature.

The semiconductor device is designed such that the thickness of the first semiconductor chip is smaller than a thickness of the second semiconductor chip; a spacer having a rectangular shape is inserted between the stage and the second semiconductor chip; or the first semiconductor chip is mounted in a recess that is formed by partially recessing the stage in its thickness direction.

The aforementioned designs reliably ensure that the surface of the first semiconductor chip be lowered in height in comparison with the surface of the second semiconductor chip. By appropriately combining the aforementioned designs, it may be possible to further increase the height difference between the first semiconductor chip and the second semiconductor chip.

When the first semiconductor chip is arranged in the recess that is formed in a first region of the stage, which is thus reduced in thickness, it is possible to reduce thermal resistance of the stage in connection with the heat-dissipation path lying from the first semiconductor chip to the substrate. Thus, it is possible to efficiently dissipate the heat of the first semiconductor chip to the substrate.

Alternatively, the semiconductor device is designed such that a slit is formed at a prescribed position of the stage between the first semiconductor chip and the second semiconductor chip and is elongated in the width direction of the semiconductor chip. Herein, the slit is formed by partially recessing the surface of the stage; the slit is formed by partially recessing the backside of the stage; or the slit runs through the stage in its thickness direction.

By way of the slit, the overall surface area of the stage is partitioned into the first and second regions for individually mounting the first and second semiconductor chips. Herein, the cross-sectional area of the stage along the alignment direction of the first and second semiconductor chips is reduced at the slit compared with the other portions of the stage. That is, thermal resistance of the stage is increased at the slit compared with the other portions of the stage. This makes it difficult for the heat of the first semiconductor chip to be transmitted from the first region to the second region in the stage. Thus, it is possible to reduce the amount of heat transmitted from the first semiconductor chip to the second semiconductor chip.

Furthermore, the slit is positioned close to the second semiconductor chip and is distanced from the center position between the first semiconductor chip and the second semiconductor chip on the stage. This increases the volume of the first region of the stage compared with the volume of the second region of the stage; hence, it is possible to reduce thermal resistance of the stage in a direction from the first semiconductor chip to the substrate. Thus, irrespective of the formation of the slit in the stage, it is possible to efficiently dissipate the heat of the first semiconductor chip to the substrate.

Incidentally, the heights of the first and second semiconductor chips in the semiconductor device are each measured from the surface of the stage or the backside of the stage to the upper surface of each semiconductor chip.

### BRIEF DESCRIPTION OF THE DRAWINGS

These and other objects, aspects, and embodiments of the present invention will be described in more detail with reference to the following drawings, in which:

FIG. 1 is a plan view showing the overall structure of a semiconductor device in accordance with a first embodiment of the present invention;

FIG. 2 is a longitudinal sectional view showing the constitution of the semiconductor device of FIG. 1 mounted on a substrate;

FIG. 3 is a plan view diagrammatically showing semiconductor chips mounted on stages of the semiconductor device, which indicates a region for forming a heating circuit and points for measuring temperature;

FIG. 4 is a longitudinal sectional view showing the semiconductor device mounted on a multilayered substrate;

FIG. 5 is a plan view showing the overall structure of a semiconductor device according to a variation of the first embodiment;

FIG. 6 is a longitudinal sectional view showing the constitution of the semiconductor device of FIG. 5 mounted on a substrate;

FIG. 7 is a plan view showing the overall structure of a semiconductor device in accordance with a second embodiment of the present invention;

FIG. 8 is a longitudinal sectional view showing the constitution of the semiconductor device of FIG. 7 mounted on a substrate;

FIG. 9 is a plan view showing the overall structure of a semiconductor device, in which a slit running through a stage is formed between semiconductor chips, in accordance with a variation of the second embodiment;

FIG. 10 is a longitudinal sectional view showing the constitution of the semiconductor device of FIG. 9 mounted on a substrate;

FIG. 11 is a longitudinal sectional view showing the constitution of a semiconductor device in which a slit is formed by partially recessing the backside of the stage;

FIG. 12 is a longitudinal sectional view showing the constitution of a semiconductor device in which a slit is formed by partially recessing the surface of the stage;

FIG. 13 is a longitudinal sectional view showing the constitution of a semiconductor device in which a second semiconductor chip is mounted on the stage via a spacer and is thus elevated in height in comparison with a first semiconductor chip causing a high heating temperature; and

FIG. 14 is a longitudinal sectional view showing the constitution of a semiconductor device in which the first semiconductor chip is mounted on a recess of the stage and is thus lowered in height in comparison with the second semiconductor chip.

### DESCRIPTION OF THE PREFERRED EMBODIMENTS

The present invention will be described in further detail by way of examples with reference to the accompanying drawings.

### 1. First Embodiment

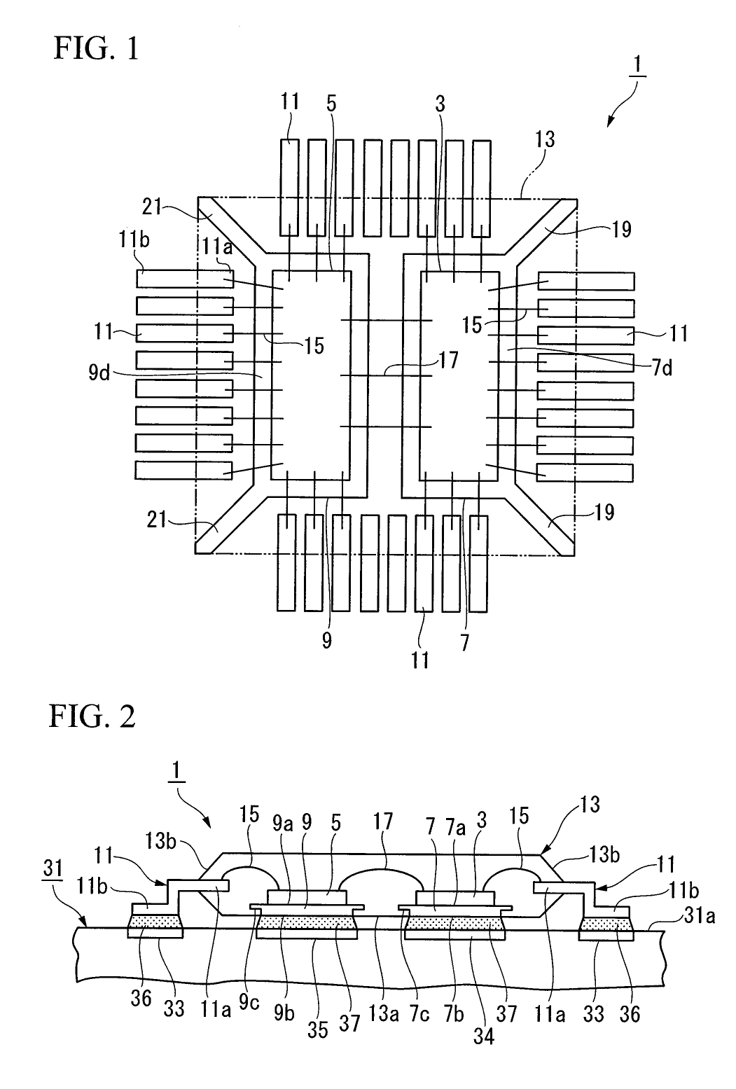

A semiconductor device 1 according to a first embodiment of the present invention will be described in detail with reference to FIGS. 1 to 4.

As shown in FIGS. 1 and 2, the semiconductor device 1 of the first embodiment is used for a power supply such as a power source for driving a speaker or a pulse-width (PW) modulating power source, wherein it includes a first semiconductor chip 3 (serving as an analog chip) and a second semiconductor chip 5 (serving as a digital chip). That is, the semiconductor device 1 is designed to cope with both of analog circuits and digital circuits.

The semiconductor device 1 is constituted of two stages 7 and 9 having surfaces 7a and 9a for mounting the semiconductor chips 3 and 5, a plurality of leads 11 that are arranged in the surrounding areas of the stages 7 and 9 and are electrically connected to the semiconductor chips 3 and 5, and a resin mold 13 for sealing the stages 7 and 9 and the leads 11. The semiconductor device 1 is packaged by way of a QFP (Quad Flat Package) in which the leads 11 partially project externally from sides 13b of the resin mold 13.

The leads 11 each having a thin band-like shape are elongated towards the stages 7 and 9 respectively, wherein first ends 11a of the leads 11 embedded inside of the resin mold 13 are electrically connected to the semiconductor chips 3 and 5 via wires 15. Second ends 11b of the leads 11 projecting externally of the resin mold 13 are bent downwardly towards a lower surface 13a of the resin mold 13 and are electrically connected to a substrate (or a circuit board) 31 for mounting the semiconductor device 1.

Each of the stages 7 and 9 has a rectangular shape in plan view and are horizontally aligned with a prescribed distance therebetween. The sides of the stages 7 and 9 are arranged along the sides 13b of the resin mold 13.

Backsides 7b and 9b of the stages 7 and 9 partially form the lower surface 13a of the resin mold 13, wherein they are exposed externally of the resin mold 13. The backside 7b of the stage 7 is partially recessed in the thickness direction of the stage 7 so as to form a recess 7c in the periphery thereof. Similarly, the backside 9b of the stage 9 is partially recessed in the thickness direction of the stage 9 so as to form a recess 9c in the periphery thereof. The resin mold 13 is partially introduced into the recesses 7c and 9c so as to prevent the stages 7 and 9 from peeling off from the resin mold 13.

The guarantee temperature of the first semiconductor chip 3 mounted on the first stage 7 is higher than the guarantee temperature of the second semiconductor chip 5 mounted on the second stage 9. Specifically, the first semiconductor chip 3 includes a heating circuit such as a pulse-width modulation (PWM) circuit, which generates a heating temperature that is higher than the guarantee temperature of the second semiconductor chip 5.

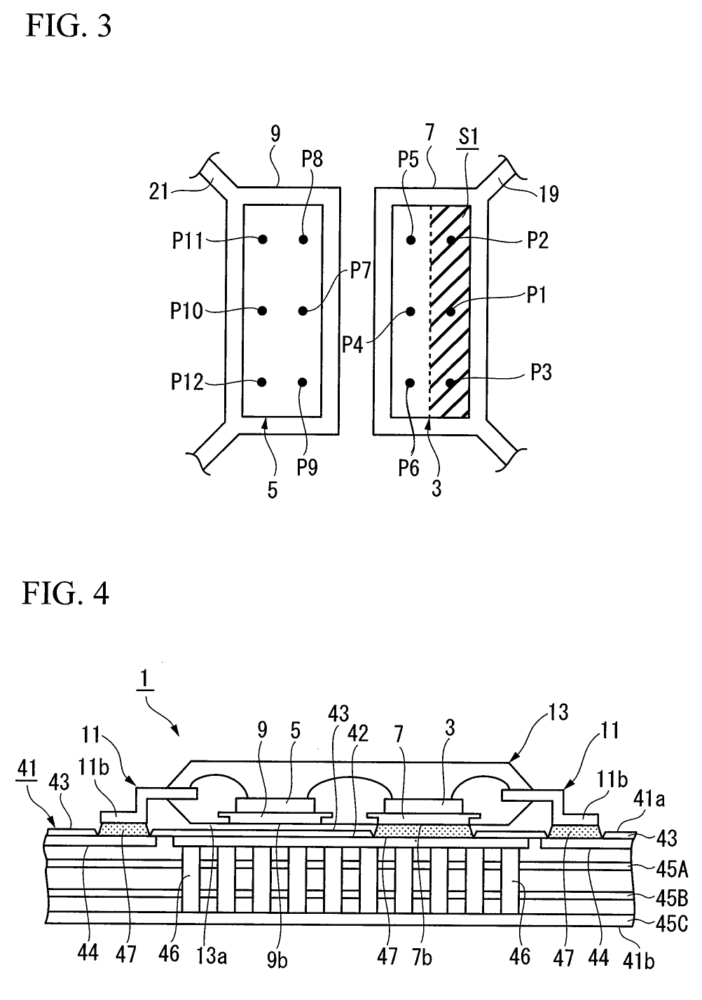

As shown in FIG. 3, the heating circuit is formed in a region St, which is included in the overall area of the first semiconductor chip 3 in plan view and is distanced from the overall area of the second semiconductor chip 5. Herein, the region S1 is arranged in the far side of the first semiconductor chip 3 distanced from the second semiconductor chip 5 along the alignment direction of the semiconductor chips 3 and 5. Specifically, the region S1 for forming the heating circuit has prescribed dimensions, in which the length thereof is substantially a half of the length of the first semiconductor chip 3, and the width thereof is substantially identical to the width of the first semiconductor chip 3.

The semiconductor chips 3 and 5 are electrically connected together via wires 17 as shown in FIGS. 1 and 2.

In the manufacturing of the semiconductor device 1 having the aforementioned constitution, a lead frame (not shown) is prepared and formed by performing press working and etching on a thin metal plate composed of a copper material and the like. The lead frame includes a frame (not shown) for collectively interconnecting all the leads 11 in connection with the second ends 11b of the leads 11 and a plurality of interconnection leads 19 and 21 for interconnecting the stages 7 and 9 to the frame as well as the stages 7 and 9 and the leads 11. That is, the lead frame is formed to integrally combine the stages 7 and 9 and the leads 11. The interconnection leads 19 are interconnected to an outer end 7d of the stage 7, and the interconnection leads 21 are interconnected to an outer end 9d of the stage 9, wherein the outer ends 7d and 9d are positioned opposite to each other in the alignment direction of the stages 7 and 9.

Incidentally, a bending process of the leads 11 can be performed simultaneously with the formation of the lead frame or performed independently of the formation of the lead frame.

After completion of the formation of the lead frame, the semiconductor chips 3 and 5 are individually mounted on the stages 7 and 9 and are then electrically connected to the first ends 11a of the leads 11 via wires 15, wherein the semiconductor chips 3 and 5 are also electrically connected together via wires 17.

Thereafter, the resin mold 13 is formed to entirely seal the semiconductor chips 3 and 5, the stages 7 and 9, the leads 11, and the wires 15 and 17. In this molding process, the semiconductor chips 3 and 5, the stages 7 and 9, the leads 11, and the wires 15 and 17 are arranged inside of a cavity of a metal mold (not shown) forming the exterior shape of the resin mold 13. The backsides 7b and 9b of the stages 7 and 9, which are exposed externally of the lower surface 13a of the resin mold 13, are arranged on the interior wall of the cavity of the metal mold, while the second ends 11b of the leads 11 and the frame are arranged externally of the cavity. In this condition, a melted resin is introduced into the cavity of the metal mold so as to form the resin mold 13.

Lastly, the lead frame sealed with the resin mold 13 is extracted from the metal mold; then, the frame and the interconnection leads 19 and 21, which are positioned externally from the resin mold 13, are cut out, thus completing the manufacturing of the semiconductor device 1.

The aforementioned semiconductor device 1 is mounted on the substrate 31. Specifically, the lower surface 13a of the resin mold 13 is positioned opposite to a surface 31a of the substrate 31, on which a plurality of electrode pads 33 and heat-dissipation pads 34 and 35 are formed. Then, the second ends 11b of the leads 11 are bonded to the electrode pads 33 via solders 36. In addition, the backsides 7b and 9b of the stages 7 and 9 are individually bonded to the heat-dissipation pads 34 and 35 via solders 37.

As described above, the stages 7 and 9 are individually bonded to the heat-dissipation pads 34 and 35, which are distanced from each other, whereby it is possible to reliably prevent the solders 37 (joining the stages 7 and 9) from being unexpectedly adhered to each other.

Next, simulation results will be described with respect to temperatures of the semiconductor chips 3 and 5 of the semiconductor device 1 in operation.

Simulation is performed with respect to the semiconductor device 1 in which the distance between the semiconductor chips 3 and 5 is set to 1.2 mm, the guarantee temperature of the first semiconductor chip 3 is set to 150° C., and the guarantee temperature of the second semiconductor chip 5 is set to 125° C. In addition, both the stages 7 and 9 have the same thermal conductivity of 342 W/mK, and the thermal conductivity of the resin mold 13 is 0.95 W/mK.

As shown in FIG. 3, the temperature of the semiconductor chip 3 is measured at six points P1 to P6 that are regularly arranged on the surface of the semiconductor chip 3, and the temperature of the semiconductor chip 5 is measured at six points P7 to P12 that are regularly arranged on the surface of the semiconductor chip 5. Specifically, the points P1 to P6 are aligned in two lines along the length direction of the semiconductor chip 3 and are also aligned in three lines along the width direction of the semiconductor chip 3. Similarly, the points P7 to P12 are aligned in two lines along the length direction of the semiconductor chip 5 and are also aligned in three lines along the width direction of the semiconductor chip 5.

The simulation is performed on a comparative example (i.e., “comparison”), in which two semiconductor chips (corresponding to the semiconductor chips 3 and 5) are mounted on a single stage, as well as an example of the semiconductor chip 1 (i.e., “embodiment”). Herein, temperature measurement is performed at the points P1 to P6 with respect to the semiconductor chip 3 serving as an analog chip. Results are shown in Table 1. In addition, temperature measurement is performed at the points P7 to P12 with respect to the semiconductor chip 5 serving as a digital chip. Results are shown in Table 2.

TABLE 1

| | Analog Chip | | | | | |
|---|---|---|---|---|---|---|
| Measurement | P1 | P2 | P3 | P4 | P5 | P6 |
| Embodiment | 152.2 | 151.6 | 151.2 | 148.4 | 148.0 | 147.8 |
| Comparison | 152.2 | 151.7 | 151.4 | 147.3 | 146.8 | 146.5 |

[Unit of measurement: ° C.]

TABLE 2

| | Digital Chip | | | | | |
|---|---|---|---|---|---|---|
| Measurement | P7 | P8 | P9 | P10 | P11 | P12 |
| Embodiment | 118.5 | 118.4 | 118.3 | 117.8 | 117.7 | 117.7 |
| Comparison | 135.8 | 135.4 | 135.4 | 134.3 | 134.1 | 134.1 |

[Unit of measurement: ° C.]

Table 1 clearly shows that similar values of temperature (about 150° C.) are measured at the points P1 to P3 arranged in the region S1 forming a heating circuit in the first semiconductor chip 3 with respect to both the embodiment and comparative example. In addition, similar values of temperature (about 147° C.) are measured at the points P4 to P6, which are arranged close to the second semiconductor chip 5 in comparison with the points P1 to P3 arranged in the region S1, with respect to both the embodiment and comparative example. Herein, the temperature at the points P4 to P6 is slightly lower than the temperature at the points P1 to P3.

Table 2 clearly shows that the temperature of the second semiconductor chip 5 of the comparative example is about 135° C., which is higher than the guarantee temperature of the second semiconductor chip 5 by 10° C. or more. This is because, in the comparative example, the heat generated by the heating circuit of the first semiconductor chip 3 is transmitted to the second semiconductor chip 5 via a single stage having a relatively high thermal conductivity.

In the embodiment compared with the comparative example, the temperature of the second semiconductor chip 5 is about 115° C., which is lower than the guarantee temperature of the second semiconductor chip 5 by 10° C. or so. This is because, in the embodiment, the semiconductor chips 3 and 5 are individually mounted on the stages 7 and 9, which are separated from each other, and only the prescribed part of the resin mold 13 having a relatively low thermal conductivity intervenes between the semiconductor chips 3 and 5, wherein it is possible to reduce the amount of heat transmitted from the first semiconductor chip 3 to the second semiconductor chip 5.

In the semiconductor device 1 of the first embodiment, the semiconductor chips 3 and 5 having different guarantee temperatures are individually mounted on the stages 7 and 9, which are slightly distanced from each other; hence, it is possible to reduce the amount of heat that is generated by the heating circuit of the first semiconductor chip 3 and is then transmitted to the second semiconductor chip 5. In short, it is possible to prevent the temperature of the second semiconductor chip 5 from unexpectedly exceeding the guarantee temperature. In other words, it is possible to reduce the amount of heat transmitted from the first semiconductor chip 3 having a relatively high guarantee temperature to the second semiconductor chip 5 having a relatively low guarantee temperature, thus improving the reliability of the semiconductor device 1.

When the semiconductor device 1 is mounted on the substrate 31, the backside 7b of the stage 7, which is exposed externally of the semiconductor device 1, is bonded to the heat-dissipation pad 34 of the substrate 31 by way of the solder 37, wherein it is possible to efficiently dissipate the heat generated by the first semiconductor chip 3 towards the substrate 31.

In addition, the semiconductor device 1 is designed such that the heating circuit is arranged in the far side of the first semiconductor chip 3, which is distanced from the second semiconductor chip 5 that is aligned to adjoin the first semiconductor chip 3. This makes it possible to increase the distance between the heating circuit and the second semiconductor chip 5; hence, it is possible to further reduce the amount of heat transmitted from the first semiconductor chip 3 to the second semiconductor chip 5.

In the packaging structure adapted to the semiconductor device 1, the heat-dissipation pads 34 and 35 that individually join the stages 7 and 9 via the solders 37 are slightly distanced from each other. This makes it possible to prevent the solders 37 joining the stages 7 and 9 from being mutually adhered to each other; hence, it is possible to reliably prevent the heat generated by the first semiconductor chip 3 from being transmitted to the second semiconductor chip 5 via the solders 27.

The semiconductor device of the first embodiment is basically designed such that the stage 9 for mounting the second semiconductor chip 5 joins the heat-dissipation pad 35; but this is not a restriction. That is, when the amount of heat generated by the second semiconductor chip 5 is very low, the stage 9 does not necessarily join the heat-dissipation pad 35. For example, it is possible to exclude the heat-dissipation pad 35 from the substrate 31, so that the second stage 9 directly joins the substrate 31 via the solder 37. In addition, the semiconductor device 1 is not necessarily mounted on the substrate 31 shown in FIG. 2. Instead, the semiconductor device 1 can be mounted on a substrate (or a circuit board) 41 shown in FIG. 4.

A heat-dissipation pad 42 having a relatively large area that is larger than the exposed area of the stage 7 is formed on a surface 41a of the substrate 41. The heat-dissipation pad 42 joins the backside 7b of the stage 7 and entirely covers the lower surface 13a of the resin mold 13.

The heat-dissipation pad 42 is covered with a resist film 43 except for a prescribed area thereof positioned opposite to the backside of the stage 7. The resist film 43 covers electrode pads 44 except for prescribed areas positioned opposite to the second end 11b of the leads 11.

A plurality of heat conduction layers 45A, 45B, and 45C, each of which is composed of a copper foil having a relatively high thermal conductivity and each of which is elongated in a plane direction of the substrate 41, are formed inside of the substrate 41 and on a backside 41b of the substrate 41. The heat conduction layers 45A to 45C are interconnected to the heat-dissipation pad 42 via a plurality of through-holes 46, which vertically run through the substrate 41 from its backside 41b to the heat-dissipation pad 42.

In order to mount the semiconductor device 1 on the substrate 41, a solder material is applied to the surface 41a of the substrate 41 by way of screen printing. Specifically, solders 47 remain on only the externally exposed portions of the electrode pads 44 and the heat-dissipation pad 42 but do not remain on the resist film 43.

In the aforementioned state, the semiconductor device 1 is mounted on the surface 41a of the substrate 41, then, solder reflows therebetween; thus, the second ends 11b of the leads 11 firmly join the electrode pads 44, and the stage 7 firmly joins the heat-dissipation pad 42.

According to the packaging structure adapted to the semiconductor device 1 mounted on the substrate 41, it is possible to diffuse the heat generated by the first semiconductor chip 3 by way of the heat-dissipation pad 42 whose area is larger than the exposed area of the stage 7. In addition, the heat is transmitted from the heat-dissipation pad 42 to the heat conduction layers 45A to 45C via the through-holes 46; hence, it is possible to realize heat dissipation regarding the first semiconductor chip 3 in an efficient way.

Since the heat-dissipation pad 42 is covered with the resist film 43, it is possible for the backside 9b of the stage 9, which is positioned opposite to the substrate 41, to directly join the heat-dissipation pad 42 without solder; hence, it is possible to reliably prevent the heat generated by the first semiconductor chip 3 from being transmitted to the second semiconductor chip 5 via the heat-dissipation pad 42.

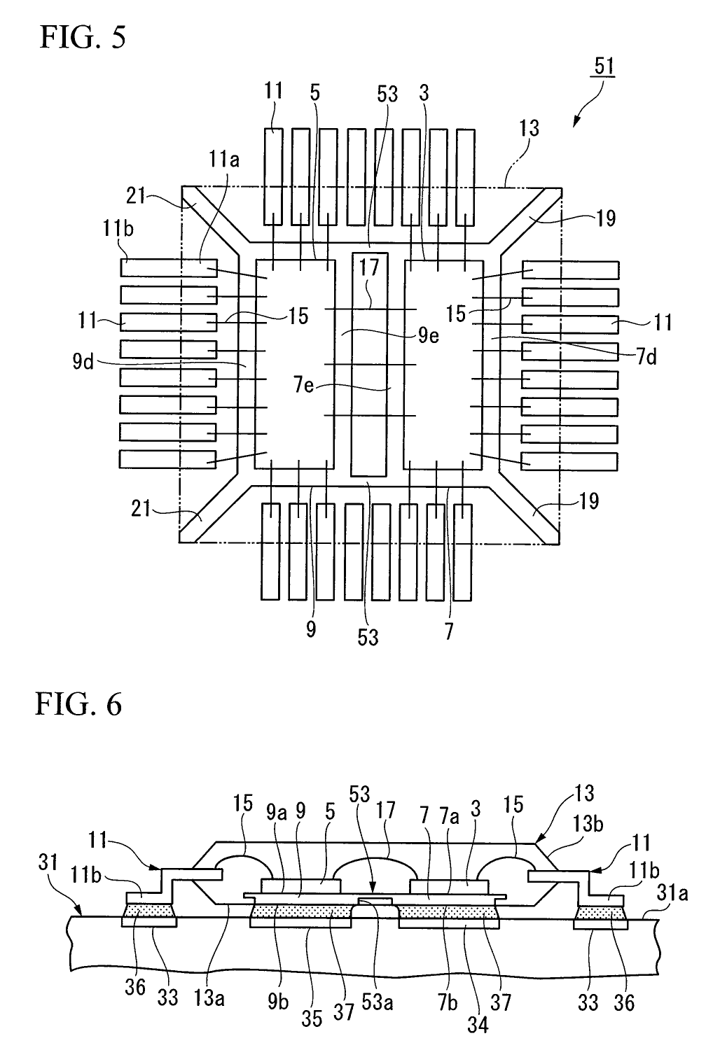

Next, a variation of the first embodiment will be described in connection with a semiconductor device 51 with reference to FIGS. 5 and 6, in which parts identical to those of the semiconductor device 1 are designated by the same reference numerals; hence, the description thereof will be omitted as necessary.

As shown in FIGS. 5 and 6, the semiconductor device 51 includes two stages 7 and 9, which are integrally interconnected together via interconnection members 53 whose widths are smaller than the widths of the stages 7 and 9. Specifically, the interconnection members 53 are integrally formed together with the stages 7 and 9 in such a way that opposite ends 7e and 9e of the stages 7 and 9 are interconnected together in the width direction via the interconnection members 53.

The interconnection members 53 have recesses 53a, which are recessed in the thickness direction from the backsides 7b and 9b of the stages 7 and 9, wherein the thickness of the recess 53a is approximately a half of the thickness of the stages 7 and 9. Due to such a structure, the interconnection members 53 are entirely embedded inside of the resin mold 13; hence, the backsides 7b and 9b of the stages 7 and 9 are exposed externally of the lower surface 13a of the resin mold 13 while they are mutually separated from each other.

In the manufacturing of the semiconductor device 51, a lead frame, which is basically designed similar to the lead frame of the semiconductor device 1 but further includes the interconnection members 53, is prepared in advance. Herein, the recesses 53a of the interconnection members 53 can be formed simultaneously with the formation of the lead frame by way of press working for partially depressing the backsides of the interconnection members 53; alternatively, they can be formed by way of etching for partially removing the backsides of the interconnection members 53. Alternatively, the recesses 53a can be formed after the formation of the lead frame.

After completion of the formation of the lead frame, similar to the manufacturing of the semiconductor device 1, the semiconductor chips 3 and 5 are individually mounted on the stages 7 and 9; then, the wires 15 are arranged between the leads 11 and the semiconductor chips 3 and 5, and the wires 17 are arranged between the semiconductor devices 3 and 5. Thereafter, the resin mold 13 is formed to entirely seal the semiconductor chips 3 and 5, the stages 7 and 9, the leads 11, and the wires 15 and 17.

Similar to the manufacturing of the semiconductor device 1, the backsides 7b and 9b of the stages 7 and 9 are arranged on the interior wall of a cavity of a metal mold (not shown); then, a melted resin is introduced into the cavity so as to form the resin mold 13, in which the backsides 7b and 9b of the stages 7 and 9 are exposed externally of the lower surface 13a of the resin mold 13. Herein, the terminal ends 7d and 9d of the stages 7 and 9 are supported by way of the leads 19 and 21, and the other ends 7e and 9e of the stages 7 and 9 are supported by way of the interconnection members 53. Hence, it is possible to easily prevent the stages 7 and 9 from unexpectedly floating from the interior wall of the cavity due to the flowing of the melted resin. In the semiconductor device 51, a pair of the interconnection members 53 interconnect both the opposite ends 7e and 9e of the stages 7 and 9; hence, it is possible to reliably prevent the opposite ends 7e and 9e of the stages 7 and 9 from unexpectedly floating in the width direction of the stages 7 and 9.

Similar to the manufacturing of the semiconductor device 1, after completion of the formation of the resin mold 13, the frame and the interconnection leads 19 and 21, which are positioned externally of the resin mold 13, are cut out so as to complete the manufacturing of the semiconductor device 51.

Similar to the semiconductor device 1, when the semiconductor device 51 is mounted on the substrate 31, the second ends 11b of the leads 11 are bonded to the electrode pads 33 via the solders 36, and the backsides 7b and 9b of the stages 7 and 9 individually join the heat-dissipation pads 34 and 35 via the solders 37.

Since the stages 7 and 9 are mutually interconnected together via the interconnection members 53, the backsides 7b and 9b thereof are separated from each other and are exposed externally of the lower surface 13a of the resin mold 13; hence, it is possible to reliably prevent the solders 37 from leaking and spreading over the stages 7 and 9.

The semiconductor device 51 demonstrates outstanding effects similar to the foregoing effects of the semiconductor device 1. In the semiconductor device 51, the heat generated by the first semiconductor chip 3 may be transmitted to the second semiconductor chip 5 via the interconnection members 53 whose widths are smaller than the widths of the stages 7 and 9, wherein it is possible to remarkably reduce the amount of heat transmitted from the first semiconductor chip 3 to the second semiconductor chip 5 via the interconnection members 53.

Due to the provision of the interconnection members 53, it is possible to prevent the stages 7 and 9 from floating above the interior wall of the cavity during the formation of the resin mold 13. This makes it possible to reliably expose the backsides 7b and 9b of the stages 7 and 9 externally of the lower surface 13a of the resin mold 13.

Since the interconnection members 53 are embedded inside of the resin mold 13, it is possible to reliably prevent the solders 37 from leaking and spreading over the stages 7 and 9. In addition, it is possible to reliably prevent the heat generated by the first semiconductor chip 3 from being transmitted to the second semiconductor chip 5 via the solders 37.

Since the interconnection members 53 interconnect the prescribed portion of the opposite ends 7e and 9e of the stages 7 and 9 lying in the width direction, it is possible to increase the length of a heat conduction path laid between the first semiconductor chip 3 and the second semiconductor chip 5 via the interconnection members 53. This makes it possible to further reduce the amount of heat transmitted from the first semiconductor chip 3 to the second semiconductor chip 5.

The semiconductor device 51 is designed such that the thickness of the interconnection members 53 is approximately a half of the thickness of the stages 7 and 9; but this is not a restriction. It is simply required that the interconnection members 53 be entirely embedded inside of the resin mold 13; in other words, it is simply required that the interconnection members 53 be formed in the recesses of the backside 7b and 9b of the stages 7 and 9. Therefore, the semiconductor device 51 can be modified in such a way that the interconnection members 53 are bent upwardly so as to project from the surfaces 7a and 9a of the stages 7 and 9.

The interconnection members 53 are not necessarily embedded inside of the resin mold 13. In order to simply prevent the stages 7 and 9 from floating in the cavity during the formation of the resin mold 13, the interconnection members 53 can be modified such that they are exposed externally of the lower surface 13a of the resin mold 13 together with the backsides 7b and 9b of the stages 7 and 9.

The interconnection members 53 are not necessarily paired or formed in a symmetrical manner. That is, it is possible to form a single interconnection member 53; alternatively, it is possible to form three or more interconnection members 53.

In the first embodiment and its variation, the backsides 7b and 9b of the stages 7 and 9 are exposed externally of the resin mold 13; but this is not a restriction. It is simply required that only the backside 7b of the stage 7 for mounting the first semiconductor chip 3 having a relatively high guarantee temperature be exposed externally of the resin mold 13.

The first embodiment is described by way of the semiconductor devices 1 and 51, each of which includes the stages 7 and 9 for individually mounting the semiconductor chips 3 and 5; but this is not a restriction. The first embodiment can be applied to other types of semiconductor devices, each of which includes three or more stages for individually mounting three or more semiconductor chips.

The first embodiment is described by way of the semiconductor devices 1 and 51 of the QFP type in which the leads 11 are partially exposed outside of the resin mold 13; but this is not a restriction. The first embodiment can be applied to semiconductor devices of a QFN (Quad Flat Non-leaded package) type in which the leads 11 are partially exposed on both the lower surface 13a and the sides 13b of the resin mold 13.

### 2. Second Embodiment

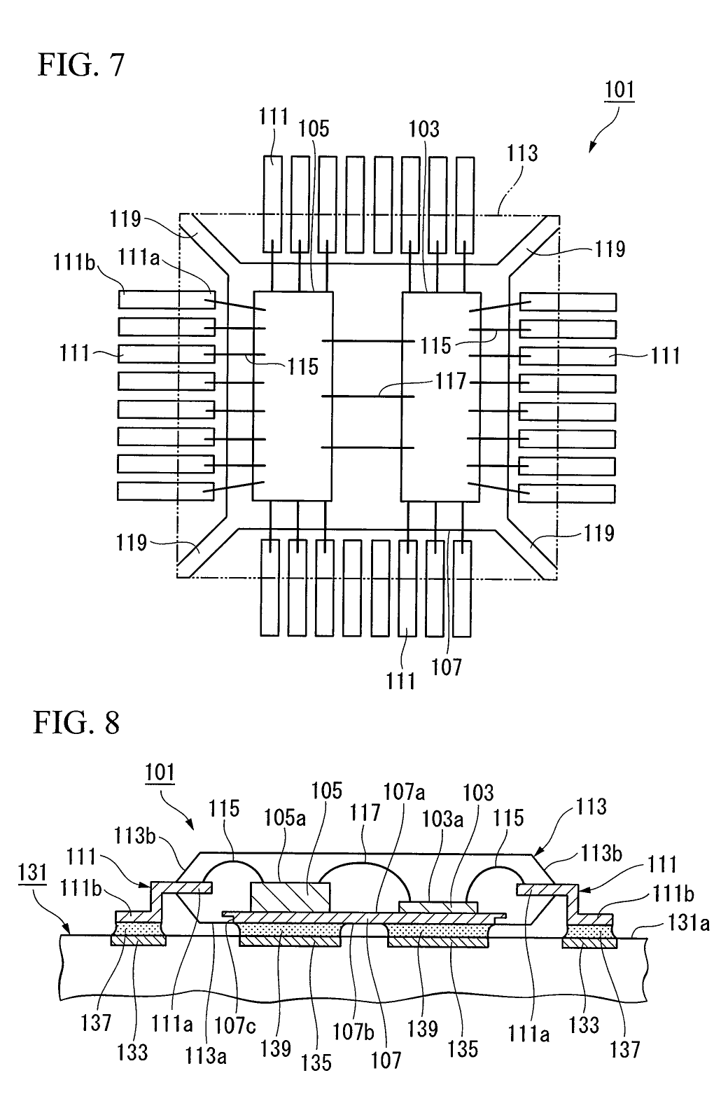

A semiconductor device 101 according to a second embodiment of the present invention will be described with reference to FIGS. 7 and 8. The semiconductor device 101 of the second embodiment is used for the power supply for supplying electric power to the circuitry, such as a power source and a pulse-width modulation (PWM) power source. The semiconductor device 101 includes a first semiconductor chip 103 (serving as an analog chip) and a second semiconductor chip 105 (serving as a digital chip). That is, the semiconductor device 101 can be adapted to both the analog circuit and digital circuit.

The semiconductor device 101 includes a stage 107 having a surface 107a on which the semiconductor chips 103 and 105 are mounted, a plurality of leads (or external connection terminals) 111 which are arranged in the periphery of the stage 107 and are electrically connected to the semiconductor chips 103 and 105 via wires 115, and a resin mold 113 for sealing the semiconductor chips 103 and 105, the stage 107, and the leads 111. The semiconductor device 101 is of a QFP (Quad Flat Package) type in which the leads 111 partially project from sides 113b of the resin mold 113.

The leads 111 are each formed in a thin band-like shape and are elongated towards the stages 107, wherein first ends 111a of the leads 111, which are embedded inside of the resin mold 113, are electrically connected to the semiconductor chips 103 and 105 via the wires 115. Second ends 111b of the leads 111, which project externally from the sides 113b of the resin mold 113, are each bent downwardly towards a lower surface 113a of the resin mold 113 and are electrically connected to a substrate (or a circuit board) 131 for mounting the semiconductor device 101.

The resin mold 113 is composed of a resin material doped with fillers composed of silica, carbon, and the like. Thus, it is possible to efficiently dissipate heat generated by the semiconductor chips 103 and 105 by way of the resin mold 113.

The stage 107 is formed in a rectangular shape having four sides, which are positioned along the sides 113b of the resin mold 113. A backside 107b of the stage 107 forms substantially the same plane with the lower surface 113a of the resin mold 113. That is, the backside 107b of the stage 107 is exposed externally of the resin mold 113.

A recess 107c is formed in the periphery of the stage 107 and is recessed in the thickness direction from the backside 107b of the stage 107. Since the resin mold 113 is partially introduced into the recess 107c, it is possible to prevent the stage 107 from separating from the resin mold 113.

The semiconductor chips 103 and 105 are arranged in a plane direction of the stage 107 and are distanced from each other, wherein they are electrically connected together via wires 117. The first semiconductor chip 103 includes an electronic circuit causing a higher heating temperature that is higher than a heating temperature caused by an electronic circuit included in the second semiconductor chip 105. That is, an electronic circuit such as a pulse-width modulation (PWM) circuit causing a higher heating temperature, which is higher than the heating temperature of an electronic circuit formed on a surface 105a of the second semiconductor chip 105, is formed on a surface 103a of the first semiconductor chip 103.

The aforementioned electronic circuit is arranged in a far-side region of the surface 103a of the first semiconductor chip 103, which is distanced from the second semiconductor chip 105 in the alignment direction of the semiconductor chips 103 and 105. For example, the length of the aforementioned region is approximately a half of the length of the first semiconductor chip 103, and the width is substantially identical to the width of the first semiconductor chip 103.

In addition, the thickness of the first semiconductor chip 103 is smaller than the thickness of the second semiconductor chip 105. Therefore, the height of the surface 103a of the first semiconductor chip 103 measured from the surface 107a of the stage 107 is lower than the height of the surface 105a of the second semiconductor chip 105. In the manufacturing of the semiconductor chips 103 and 105, back grinding is performed on the lower surface of a wafer before being divided into individual pieces corresponding to the semiconductor chips 103 and 105 by controlling the amount of grinding performed on the wafer in connection with the semiconductor chips 103 and 105, thus realizing different thicknesses with respect to the semiconductor chips 103 and 105.

Specifically, when the semiconductor chips 103 and 105 are produced using a single wafer whose thickness is 625 μm, the amount of grinding applied to the first semiconductor chip 103 is set to 25 μm so that the thickness of the first semiconductor chip 103 is 600 μm, and the amount of grinding applied to the second semiconductor chip 105 is set to 425 μm so that the thickness of the second semiconductor chip 105 is 200 μm, for example.

Of course, it is possible to use two wafers having different thicknesses for use in the manufacturing of the semiconductor chips 103 and 105 having different thicknesses.

In the manufacturing of the semiconductor device 101, a lead frame (not shown) is prepared and produced using a thin metal plate composed of a copper material, which is subjected to press working and etching. The lead frame includes a frame (not shown) for integrally interconnecting the second ends 111b of the leads 111 and a plurality of interconnection leads 119 for interconnecting the frame to the stage 107, in addition to the stage 107 and the leads 111. The interconnection leads 119 are interconnected to the corners of the stage 107 having a rectangular shape. That is, the lead frame is shaped to integrally interconnect the stage 107 and the lead 111 together.

The bending process of the leads 111 can be simultaneously with or independently of the formation of the lead frame.

After completion of the formation of the lead frame, the semiconductor chips 103 and 105 are mounted on the surface 107a of the stage 107 and are then electrically connected to the first ends 111a of the leads 111, wherein the semiconductor chips 103 and 105 are electrically connected together via the wires 117.

Then, the resin mold 113 is formed to entirely seal the semiconductor chips 103 and 105, the stages 107, the leads 111, and the wires 115 and 117 therein. Specifically, the semiconductor chips 103 and 105, the stage 107, the leads 111, and the wires 115 and 117 are arranged inside of a cavity of a metal mold forming the external shape of the resin mold 113. Herein, the backside 107b of the stage 107, which is exposed externally of the resin mold 113, is arranged on the interior wall of the cavity of the metal mold, while the second ends 111b of the leads 111 and the frame are arranged outside of the cavity of the metal mold. In this state, a melted resin is introduced into the cavity so as to form the resin mold 113.

Thereafter, the lead frame sealed with the resin mold 113 is extracted from the metal mold; then, the frame and the interconnection leads 119, which are positioned externally of the resin mold 113, are cut out so as to complete the manufacturing of the semiconductor device 101.

The semiconductor device 101 is mounted on the substrate 131 in such a way that the lower surface 113a of the resin mold 113 is positioned opposite to the surface 131a of the substrate 131, on which a plurality of electrode pads 133 and a heat-dissipation pad 135 are formed as shown in FIG. 8; then, the second ends 111b of the leads 111 are bonded to the electrode pads 133 via solders 137. In addition, the backside 107b of the stage 107 is bonded to the heat-dissipation pad 135 via a solder 139. After completion of the packaging described above, a heat-dissipation path is formed from the surface 103a of the first semiconductor chip 103 to the heat-dissipation pad 135 of the substrate 131 via the stage 107 and the solder 139.

The semiconductor device 101 is designed such that, compared with the surface 105a of the second semiconductor chip 105, the surface 103a of the first semiconductor chip 103 is positioned close to the surface 107a of the stage 107. This makes it possible to reduce the heat-dissipation path lying from the electronic circuit of the first semiconductor chip 103 to the heat-dissipation pad 135 of the substrate 131 via the stage 107 and the solder 139.

In addition, the semiconductor device 101 is characterized in that the total volume of the stage 107 collectively mounting the semiconductor chips 103 and 105 can be increased to be larger than the total volume of two stages individually mounting two semiconductor chips. This makes it possible to further reduce thermal resistance of the stage 107 in connection with the heat-dissipation path lying from the first semiconductor chip 103 to the substrate 131. Thus, it is possible to efficiently dissipate heat generated by the first semiconductor chip 103 to the substrate 131.

In the semiconductor device 101, it is possible to increase the distance between the surface 103a of the first semiconductor chip 103 and the surface 105a of the second semiconductor chip 105 without broadening the gap between the semiconductor chips 103 and 105, wherein the direction from the surface 103a of the first semiconductor chip 103 to the surface 105a of the second semiconductor chip 105 is reverse to the direction of the heat-dissipation path from the surface 103a of the first semiconductor chip 103 to the substrate 131; hence, it is possible to prevent the heat, which is generated on the surface 103a of the first semiconductor chip 103, from being transmitted to the surface 105a of the second semiconductor chip 105. That is, it is possible to prevent the temperature of the second semiconductor chip 105 from exceeding the guarantee temperature, thus improving the reliability of the semiconductor device 101.

The second embodiment is not necessarily limited to the aforementioned semiconductor device 101 and can be modified in a variety of ways.

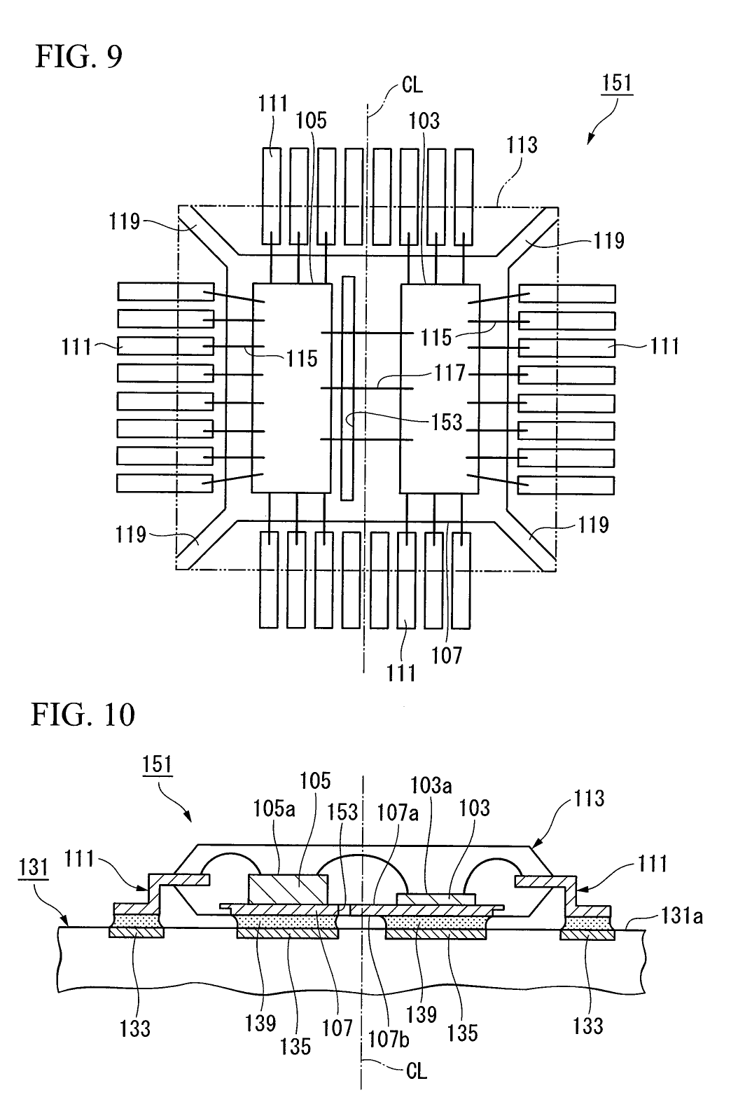

Next, a variation of the second embodiment will be described in connection with a semiconductor device 151 with reference to FIGS. 9 and 10, wherein parts identical to those of the semiconductor device 101 are designated by the same reference numerals; hence, the detailed description thereof will be omitted.

As shown in FIGS. 9 and 10, a slit 153 is formed at a prescribed position of the stage 107 between the semiconductor chips 103 and 105, wherein the slit 153 runs through the stage 107 from the surface 107a to the backside 107b. The slit 153 is elongated in a direction perpendicular to the alignment direction of the semiconductor chips 103 and 105, wherein the length of the slit 153 is longer than the widths of the semiconductor chips 103 and 105. That is, the overall area of the stages 107 is partitioned into a first region for mounting the first semiconductor chip 103 and a second region for mounting the second semiconductor chip 105 by way of the slit 153.

In addition, the slit 153 is formed at the prescribed position, which is close to the second semiconductor chip 105 and is slightly distanced from a center position CL of the gap between the semiconductor chips 103 and 105, whereby the first region becomes larger than the second region in the stage 107. The slit 153 can be formed by way of press working or etching simultaneously with or after the formation of the lead frame.

The semiconductor device 151 demonstrates effects similar to the foregoing effects of the semiconductor device 101. The sectional area of the stage 107 lying perpendicular to the alignment direction of the semiconductor chips 103 and 105 is reduced at the slit 153 compared with the other portions of the stage 107. In other words, thermal resistance of the stage 107 is increased at the slit 153 compared with the other portions of the stage 107. This makes it difficult for the heat generated by the first semiconductor chip 103 to be transmitted from the first region to the second region in the stage 107; thus, it is possible to remarkably reduce the amount of heat transmitted from the first semiconductor chip 103 to the second semiconductor chip 105.

Since the slit 153 is formed at the prescribed position that is close to the semiconductor chip 105 rather than the center position CL, the volume of the first region becomes larger than the volume of the second region in the stage 107, whereby thermal resistance of the stage 107 is reduced with respect to the direction from the first semiconductor chip 103 to the substrate 131. That is, irrespective of the formation of the slit 153 in the stage 107, it is possible to efficiently dissipate the heat generated by the first semiconductor chip 103 to the substrate 131.

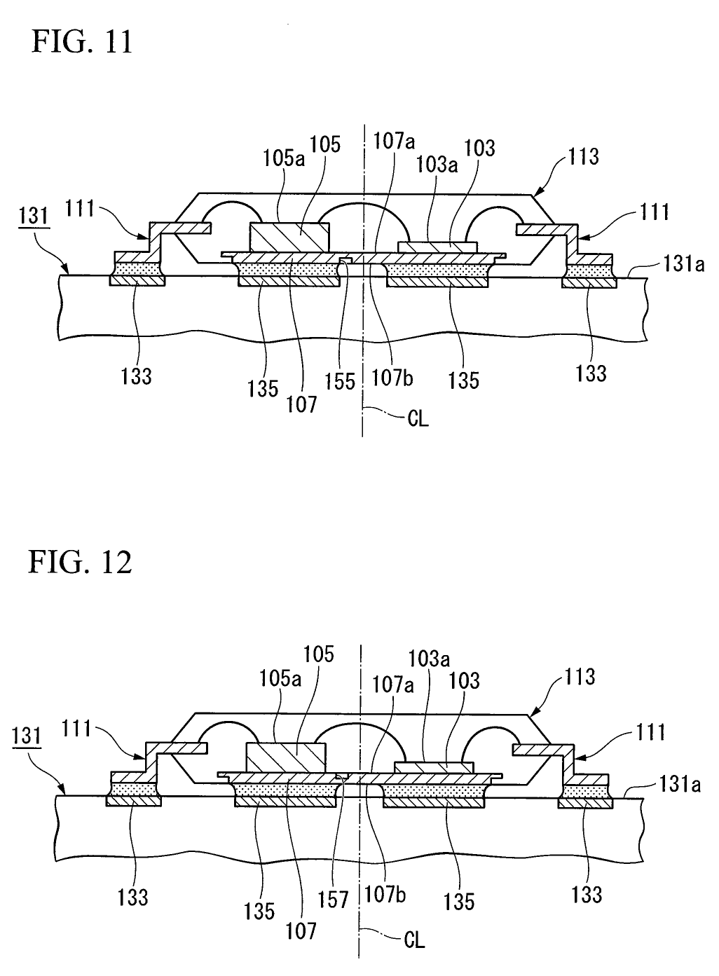

The semiconductor device 151 is designed such that the slit running through the stage 107 in its thickness direction is formed in the gap between the semiconductor chips 103 and 105; but this is not a restriction. For example, as shown in FIG. 11, a slit 155 is formed by partially recessing the backside 107b of the stage 107. Alternatively, a slit 157 is formed by partially recessing the surface 107a of the stage 107. Each of the slits 153, 155, and 157 is not necessarily formed as a single channel; that is, each of them can be divided into plural sections.

Each of the second embodiment and its variations is designed such that the thickness of the first semiconductor chip 103 is smaller than the thickness of the second semiconductor chip 105, wherein it is simply required that the surface 103a of the first semiconductor chip 103 is lower than the surface 105a of the second semiconductor chip 105 in height above the surface 107a of the stage 107; therefore, both the semiconductor chips 103 and 105 can be modified to have the same thickness.

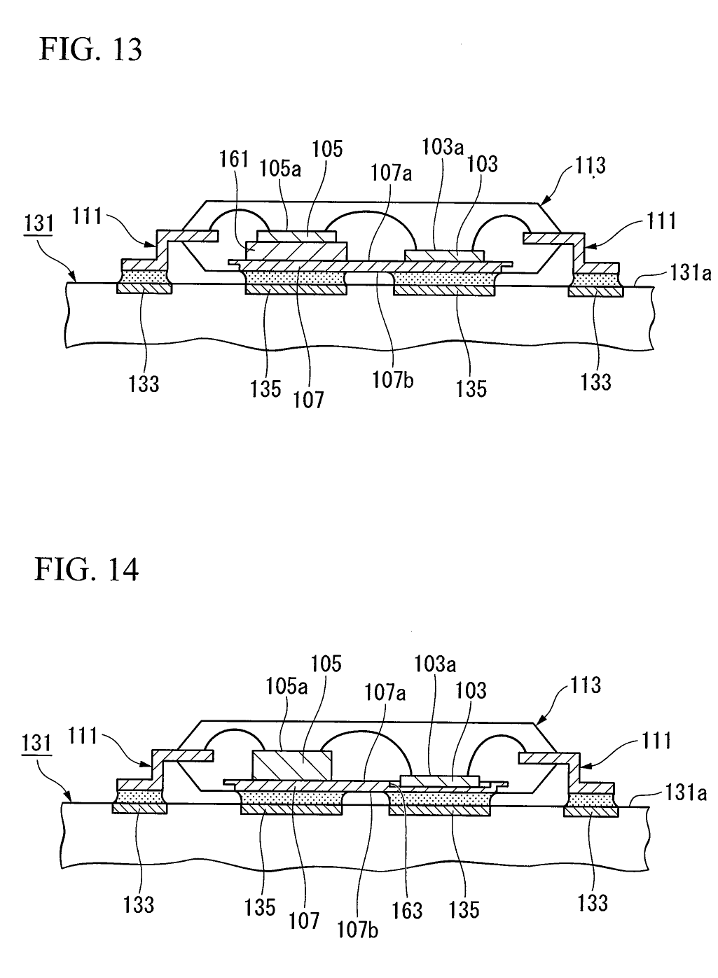

As shown in FIG. 13, it is possible to insert a spacer 161 having a rectangular shape between the stage 107 and the second semiconductor chip 105. The spacer 161 can be formed using various materials. For example, the spacer 161 is formed using an adhesive having an electrically insulating ability (e.g., a die-bond film) for fixing the second semiconductor chip 105 to the stage 107. It is preferable that the spacer 161 be formed using a resin material having a relatively low thermal conductivity. Herein, it is preferable that the resin material be doped with fillers different from the fillers used in the resin mold 113. This makes it further difficult to transmit the heat generated by the first semiconductor chip 103 to the second semiconductor chip 105 in the heat-transmission path lying from the first semiconductor chip 103 to the second semiconductor chip 105 via the stage 107; thus, it is possible to further improve the reliability of the semiconductor device.

As shown in FIG. 14, it is possible to form a recess 163, which is recessed from the surface 107a of the stage 107 in its thickness direction and in which the first semiconductor chip 103 is mounted on the bottom, thus lowering the surface 103a of the first semiconductor chip 103 to be lower than the surface 105a of the second semiconductor device 105 in height. The recess 163 is formed by way of etching simultaneously with the formation of the lead frame; alternatively, the recess 163 is formed by way of etching independently performed after the formation of the lead frame.

In the above, the first region of the stage 107 for mounting the first semiconductor chip 103 is reduced in thickness; hence, it is possible to further reduce thermal resistance of the stage 107 in connection with the heat-dissipation path from the first semiconductor chip 103 to the substrate 131. This makes it possible to efficiently dissipate the heat generated by the first semiconductor chip 103 to the substrate 131.

The second embodiment and its variations are directed to the semiconductor devices 101 and 151, each of which includes the semiconductor chips 103 and 105; but this is not a restriction. That is, the second embodiment can be applied to other types of semiconductor devices each including three or more semiconductor chips. In a semiconductor device including three semiconductor chips, for example, a first semiconductor chip causing a highest heating temperature is lowered in height in comparison with second and third semiconductor chips, and the second semiconductor chip causing a heating temperature, which is lower than the heating temperature of the first semiconductor chip but is higher than the heating temperature of the third semiconductor chip, is lowered in height in comparison with the third semiconductor chip.

Both of the semiconductor devices 101 and 151 are of the QFP type in which the leads 111 partially project externally from the resin mold 113; but this is not a restriction. That is, the second embodiment is applicable to any types of semiconductor devices such as the QFN (Quad Flat Non-leaded package) type in which the leads 111 are partially exposed on both of the lower surface 113a and the sides 113b of the resin mold 113, the BGA (Ball Grid Array) type in which ball electrodes are arranged on the backside of a package in a grid manner, and the LGA (Land Grid Array) type in which instead of ball electrodes, flat electrode pads are arranged on the backside of a package in a grid manner.

Lastly, the present invention is not necessarily limited to the first and second embodiments as well as their variations, all of which can be further modified in a variety of ways within the scope of the invention defined by the appended claims.

What is claimed is:

1. A semiconductor device comprising:
a plurality of stages each having a rectangular shape, which are positioned in a same plane and which are distanced from each other;
a plurality of semiconductor chips including a first semiconductor chip and a second semiconductor chip, which are individually mounted on surfaces of the stages, wherein the first semiconductor chip causes a heating temperature that is higher than a heating temperature caused by the second semiconductor chip; and
a resin mold for sealing the plurality of semiconductor chips and the plurality of stages therein, wherein at least a backside of the stage for mounting the first semiconductor chip is exposed externally of the resin mold.

2. A semiconductor device according to claim 1, wherein a heating circuit is formed in a prescribed region of the first semiconductor chip that is distanced from the second semiconductor chip.

3. A semiconductor device according to claim 1, wherein the plurality of stages are positioned adjacent to each other, and which are integrally interconnected together by way of at least one interconnection member whose width is smaller than the width of each stage.

4. A semiconductor device according to claim 2, wherein the plurality of stages are positioned adjacent to each other, and which are integrally interconnected together by way of at least one interconnection member whose width is smaller than the width of each stage.

5. A semiconductor device according to claim 3, wherein the interconnection member is formed by way of a recess that is recessed from the backside of the stage in its thickness direction.

6. A semiconductor device according to claim 4, wherein the interconnection member is formed by way of a recess that is recessed from the backside of the stage in its thickness direction.

7. A semiconductor device according to claim 3, wherein both ends of one stage and both ends of another stage are interconnected together via the interconnection member in a width direction.

8. A semiconductor device according to claim 4, wherein both ends of one stage and both ends of another stage are interconnected together via the interconnection member in a width direction.

9. A packaging structure adapted to a semiconductor device including:
a plurality of stages each having a rectangular shape, which are positioned in a same plane and which are distanced from each other;
a plurality of semiconductor chips including a first semiconductor chip and a second semiconductor chip, which are individually mounted on surfaces of the stages, wherein the first semiconductor chip causes a heating temperature that is higher than a heating temperature of the second semiconductor chip; and
a resin mold for sealing the plurality of semiconductor chips and the plurality of stages therein, wherein at least a backside of the stage for mounting the first semiconductor chip is exposed externally of the resin mold,
said packaging structure further including at least one heat-dissipation pad having a prescribed area for joining the backside of the stage for mounting the first semiconductor chip, wherein an overall area of the heat-dissipation pad is larger than an exposed area of the backside of the stage that is exposed externally of the resin mold, and wherein the heat-dissipation pad is covered with a resist film except for the prescribed area that is positioned opposite to the backside of the stage.

10. A semiconductor device comprising:
a plurality of semiconductor chips including a first semiconductor chip and a second semiconductor chip;
a single stage having a rectangular shape, on which surface the plurality of semiconductor chips are mounted;
a plurality of leads whose first ends are electrically connected to the plurality of semiconductor chips; and
a resin mold for sealing the semiconductor chips, the stage, and the first ends of the leads in such a way that a prescribed area of a backside of the stage and second ends of the leads are exposed externally thereof,
wherein the first semiconductor chip causes a heating temperature that is higher than a heating temperature of the second semiconductor chip,
and wherein a height of the first semiconductor chip relative to the surface of the stage is lower than that of the second semiconductor chip.

11. A semiconductor device according to claim 10, wherein a guarantee temperature of the second semiconductor chip is lower than a guarantee temperature of the first semiconductor chip.

12. A semiconductor device according to claim 10, wherein a thickness of the first semiconductor chip is smaller than a thickness of the second semiconductor chip.

13. A semiconductor device according to claim 10, wherein a spacer having a rectangular shape is inserted between the stage and the second semiconductor chip.

14. A semiconductor device according to claim 10, wherein the first semiconductor chip is mounted in a recess that is formed by partially recessing the stage in its thickness direction.

15. A semiconductor device according to claim 10 further comprising a slit, which is formed at a prescribed position of the stage between the first semiconductor chip and the second semiconductor chip and which is elongated in a width direction of the semiconductor chip.

16. A semiconductor device according to claim 15, wherein the slit is formed by partially recessing the surface of the stage.

17. A semiconductor device according to claim 15, wherein the slit is formed by partially recessing the backside of the stage.

18. A semiconductor device according to claim 15, wherein the slit runs through the stage in its thickness direction.

19. A semiconductor device according to claim 15, wherein the slit is positioned close to the second semiconductor chip and is distanced from a center position between the first semiconductor chip and the second semiconductor chip on the stage.

20. A semiconductor device comprising:
a plurality of semiconductor chips including a first semiconductor chip and a second semiconductor chip;
a single stage having a rectangular shape for mounting the plurality of semiconductor chips;
a plurality of leads whose first ends are electrically connected to the plurality of semiconductor chips; and
a resin mold for sealing the semiconductor chips, the stage, and the first ends of the leads in such a way that a prescribed area of a backside of the stage and second ends of the leads are exposed externally thereof,
wherein the first semiconductor chip causes a heating temperature that is higher than a heating temperature of the second semiconductor chip,
and wherein a height of the first semiconductor chip relative to the backside of the stage is lower than that of the second semiconductor chip.

21. A semiconductor device according to claim 20, wherein a guarantee temperature of the second semiconductor chip is lower than a guarantee temperature of the first semiconductor chip.

22. A semiconductor device according to claim 20, wherein a thickness of the first semiconductor chip is smaller than a thickness of the second semiconductor chip.
